(19) United States
(12) Patent Application Publication
(10) Pub. No.: US 2024/0419862 A1
(43) Pub. Date: Dec. 19, 2024

(54) APPARATUS AND METHOD FOR PREDICTING CROP PEST AND DISEASE RISK USING TIME-SERIES ENVIRONMENTAL DATA

(71) Applicant: SHERPA SPACE INC., Daejeon (KR)

(72) Inventor: Choa Mun YUN, Daejeon (KR)

(21) Appl. No.: 18/610,414

(22) Filed: Mar. 20, 2024

(30) Foreign Application Priority Data
Jun. 19, 2023 (KR) 10-2023-0078492
Dec. 21, 2023 (KR) 10-2023-0189088

(51) Int. Cl. G06F 30/20

(52) U.S. Cl. CPC G06F 30/20

(57) ABSTRACT

Proposed are an apparatus and method for predicting a crop pest and disease risk using time-series environmental data, by which a prediction model for predicting a crop pest and disease risk according to changes in a growth environment is generated by collecting and analyzing time-series public environmental data such as temperature, humidity, CO₂ concentration, and solar radiation at a crop cultivation site, and a treatment recipe for taking a rapid action before pests and diseases occur or at an early stage using the prediction model is provided.

### CROSS-REFERENCE TO RELATED APPLICATIONS

This application claims the priority of Korean Patent Application No. 10-2023-0078492 filed on Jun. 19, 2023, and Korean Patent Application No. 10-2023-0189088 filed on Dec. 21, 2023, in the Korean Intellectual Property Office, the disclosure of which are incorporated herein by reference in their entirety.

### BACKGROUND OF THE INVENTION

### Field of the Invention

The present invention relates to a technology for predicting the risk of pests and diseases of crops using time-series environmental data, and more specifically, to an apparatus and method for predicting the risk of pests and diseases of crops using time-series environmental data, by which a prediction model for predicting a crop pest and disease risk according to changes in a growth environment is generated by collecting and analyzing time-series public environmental data such as temperature, humidity, CO₂ concentration, and solar radiation in a crop cultivation site, and a treatment recipe for taking a rapid action before pests and diseases occur or at an early stage using the prediction model is provided.

### Description of the Related Art

Disease and insect injury includes pests and diseases. Diseases refer to the death and decay of all useful plants, including agricultural crops such as grains, vegetables, fruit trees, flowers, and forest trees, by germs, resulting in reduced yield or poor quality. Insect injury refers to feeding damage, and absorption damage, and the like by insects. Here, insects that cause damage to plants are called pests.

Diseases are caused by pathogens parasitic on plants, and spread rapidly and have a wide range of damage. The degree of damage from diseases varies greatly depending on the type of pathogen, type of crop, variety, time of occurrence of disease, and weather conditions. In hospitals, there are fungi, bacteria, mycoplasma, viruses, viroids, etc. In addition to insects, pests also include mites and nematodes, and methods of causing damage vary depending on the type of pest.

However, in the past, pesticides were sprayed after leaving pests unattended until they were visible, and thus there was a problem that spraying the pesticides has little effect when pests and diseases are in advanced stages.

In addition, the use of pesticides to treat pests and diseases causes environmental damage, and thus it is necessary to predict and respond to pests and diseases before they occur.

Recently, data of various modalities is used to predict crop pests and diseases by applying machine learning methods.

In particular, the occurrence of pests and diseases is predicted by creating a prediction model based on factors such as the crop genome, crop nutrients, and microbial pathogens. This method has the advantage of high accuracy in determining pests and diseases, but it is difficult to collect and manage factors such as the crop genome, crop nutrients, and microbial pathogens, which limits the use of the factors in modeling.

Meanwhile, technology is also being used to interpret predictions, such as fundamental biological mechanisms, through models targeting specific crops.

For example, a model for predicting Inua infection in apples calculates environmental variables and several intermediate variables to predict whether or not pests and diseases will occur.

Such a conceptual modeling method has the advantage of being able to interpret predictions such as fundamental biological mechanisms through the model, but it uses many variables to predict pests and diseases, and a deep understanding of both a target pest and disease and crop is essential for integrating variables. As a result, when the target crop or pest and disease for model application is changed, a new model needs to be created or the existing model needs to be heavily adjusted, and there is also a disadvantage that it is impossible to create a model for a wide range of crops and pests and diseases.

Korea Patent Publication No. 10-2023-0128600 discloses a technology for analyzing crop pest and disease images to create an artificial intelligence model for determining crop pests and diseases and determining crop pests and diseases using the generated model.

However, the determining method of analyzing crop photographs, such as the prior art, not only has the disadvantage of requiring a large amount of resources for algorithm calculations, but also requires that a certain degree of pests and diseases be present before determination, and thus there is a limitation in that the method is not carried out as a preventative measure before pests and diseases occur.

### CITED REFERENCE

### Patent Document

Korea Patent Publication No. 10-2023-0128600 (Sep. 5, 2023)

### SUMMARY OF THE INVENTION

Therefore, the present invention has been made in view of the above problems, and it is an object of the present invention to provide an apparatus and method for predicting a crop pest and disease risk using time-series environmental data, by which it is possible to predict the risk of pests and diseases that may occur in crops by performing machine learning on large-scale environmental data on multiple crops and pests and diseases.

An object of the present invention is to provide an apparatus and method for predicting a crop pest and disease risk using time-series environmental data, by which it is possible to predict the occurrence of pests and diseases in crops only with crop growth environment information in general situations by using public environmental data that can be relatively easily collected and applying deep learning methods.

In order to achieve the above objects, the present invention proposes, as an embodiment, an apparatus for predicting a crop pest and disease risk using time-series environmental data.

In accordance with an aspect of the present invention, the above and other objects can be accomplished by the provision of an apparatus for predicting a crop pest and disease risk using time-series environmental data, the apparatus including a growth DB for constructing a data set including time-series growth environment information including temperature and humidity of a crop cultivation site and information on pests and diseases of crops according to changes in a growth environment, an analyzer configured to perform machine learning on the data set to create a risk prediction model for pests and diseases of crops according to changes in the growth environment, a predictor configured to receive accumulated growth environment information of a target cultivation site and to calculate a risk of pests and diseases occurring in crops at the target cultivation site using the risk prediction model, and a prescription device configured to generate an environment creation recipe for the target cultivation site on the basis of the calculated risk.

In an embodiment of the apparatus, the growth environment information may include facility horticulture environment information including at least one of a temperature, a humidity, a light amount, a CO₂ concentration, a dew point, or a soil temperature, and open field horticulture environment information including at least one of a temperature, a humidity, a rainfall amount, a soil temperature, a soil humidity, a wind speed, a wind direction, or a dew point.

In an embodiment of the apparatus, the environment creation recipe may include at least one of temperature control, humidity control, light amount control, CO₂ control, dew point control, or soil temperature control in the case of facility horticulture.

In an embodiment of the apparatus, the apparatus may further include a diagnostic device configured to analyze images of crops provided from an imaging device installed at the target cultivation site to determine the type and progress of pests and diseases occurring in the crops.

In an embodiment of the apparatus, the growth DB may further construct a data set including images of normal crops and images of pest-infested crops, and the apparatus may further includes a determination device configured to determine pests and diseases through ensemble learning of pest detection algorithms using the crop image data set and to select an optimal pest detection algorithm according to the type of crops and the growth environment information, wherein the diagnostic device may determine the type and progress of pests and diseases occurring in the crops using the selected pest detection algorithm.

In an embodiment of the apparatus, the prescription device may further generate a control recipe depending on the determined type and progress of pests and diseases.

In an embodiment of the apparatus, the diagnostic device may receive the images of the crops from the imaging device only when the risk calculated by the predictor is equal to or higher than a preset reference level.

In an embodiment of the apparatus, the apparatus may further include a setting device configured to instruct the imaging device to change an imaging cycle depending on the type and progress of pests and diseases when the type and progress of pests and diseases are determined by the diagnostic device.

Further, in order to achieve the above objects, the present invention proposes a method for predicting a crop pest and disease risk using time-series environmental data as another embodiment.

In accordance with another aspect of the present invention, there is provided a method for predicting a crop pest and disease risk using time-series environmental data by a risk prediction apparatus, the method including constructing, by a growth DB of the prediction apparatus, a data set including time-series growth environment information including temperature and humidity of a crop cultivation site and information on pests and diseases of crops according to changes in a growth environment, performing, by an analyzer of the prediction apparatus, machine learning on the data set to create a risk prediction model for pests and diseases of crops according to changes in the growth environment, receiving accumulated growth environment information of a target cultivation site and calculating a risk of pests and diseases occurring in crops at the target cultivation site using the risk prediction model by a predictor of the prediction apparatus, and generating, by a prescription device of the prediction apparatus, an environment creation recipe for the target cultivation site on the basis of the calculated risk.

In an embodiment of the method, the growth environment information may include facility horticulture environment information including at least one of a temperature, a humidity, a light amount, a CO₂ concentration, a dew point, or a soil temperature, and open field horticulture environment information including at least one of a temperature, a humidity, a rainfall amount, a soil temperature, a soil humidity, a wind speed, a wind direction, or a dew point.

In an embodiment of the method, the environment creation recipe may include at least one of temperature control, humidity control, light amount control, CO₂ control, dew point control, or soil temperature control in the case of facility horticulture.

In an embodiment of the method, the method may further include analyzing, by a diagnostic device of the prediction apparatus, images of crops provided from an imaging device installed at the target cultivation site to determine the type and progress of pests and diseases occurring in the crops.

In an embodiment of the method, the determining of the type and progress of pests and diseases occurring in the crops may include further constructing, by the growth DB, a data set including images of normal crops and images of pest-infested crops, determining pests and diseases through ensemble learning of pest detection algorithms using the crop image data set and selecting an optimal pest detection algorithm according to the type of crops and the growth environment information by a determination device of the prediction apparatus, and determining, by the diagnostic device, the type and progress of pests and diseases occurring in the crops using the selected pest detection algorithm.

In an embodiment of the method, the prescription device may further generate a control recipe depending on the determined type and progress of pests and diseases.

In an embodiment of the method, the diagnostic device may receive the images of the crops from the imaging device only when the risk calculated by the predictor is equal to or higher than a preset reference level.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a schematic diagram showing an overall system for predicting the risk of pests and diseases of crops using time-series environmental data according to Embodiment 1 of the present invention;

FIG. 2 is a block diagram showing the detailed configuration of a prediction apparatus illustrated in FIG. 1;

FIG. 3 is a schematic diagram of a data collection and prediction model;

FIG. 4 is a diagram illustrating an autoencoder structure and optimal embedding for a latent space;

FIG. 5 is a diagram showing two-dimensional embedding of test data;

FIG. 6 is a diagram showing a distribution of risk scores for normal and infected samples for each crop and each pest and disease;

FIG. 7 is a diagram showing prediction results for crops and pests and diseases;

FIG. 8(a) is a diagram showing a distribution of risk scores corresponding to the severity of observed occurrence;

FIG. 8(b) is a diagram showing verification of a gray mold prediction model using a data set;

FIG. 9 is a schematic diagram showing an overall system for predicting the risk of pests and diseases of crops using time-series environmental data according to Embodiment 2 of the present invention;

FIG. 10 is a block diagram showing the detailed configuration of a prediction apparatus 200 illustrated in FIG. 9;

FIG. 11 is a flowchart showing a method for predicting the risk of pests and diseases of crops according to Embodiment 3 of the present invention; and

FIG. 12 is a flowchart showing a method for determining the type and progress of pests and diseases by analyzing images of crops in Embodiment 3.

### DETAILED DESCRIPTION OF THE INVENTION

Hereinafter, several embodiments of the present invention will be described in detail with reference to the accompanying drawings. It should be understood, however, that there is no intent to limit the embodiments to the particular forms disclosed, but on the contrary, the embodiments should be construed as including all modifications, equivalents, and substitutions falling within the spirit and scope of the present invention.

In this specification, singular expressions include plural expressions, unless the context clearly dictates otherwise.

In this specification, when it is stated that a certain component “has” or “comprises” a sub-component, it does not exclude other components but may further include other components unless specifically stated to the contrary.

In this specification, the terms “unit”, “module”, and “component” refer to a unit that processes at least one function or operation, and the unit may be implemented through hardware, software, or a combination of hardware and software.

In this specification, the description “connected” may mean that two components are directly connected, but is not necessarily limited thereto, and may also mean that they are connected via one or more other components disposed between the components.

### Embodiment 1

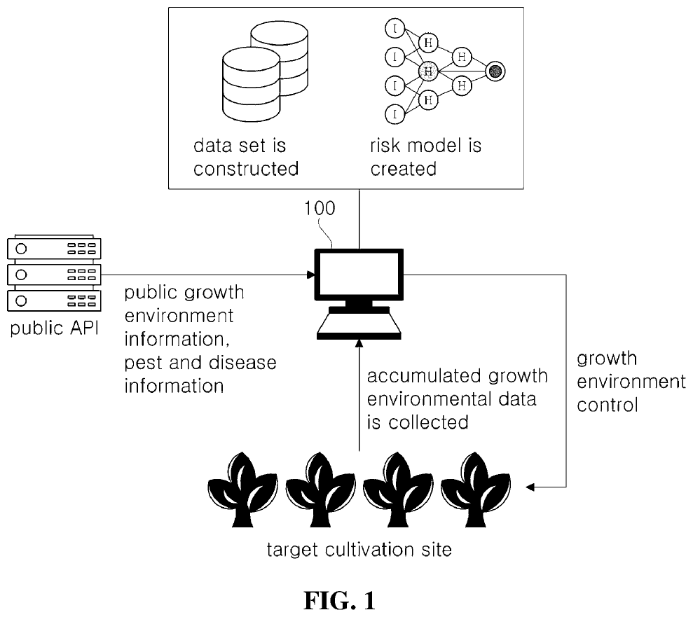

FIG. 1 is a schematic diagram showing an overall system for predicting the risk of pests and diseases of crops using time-series environmental data according to Embodiment 1 of the present invention.

As shown in FIG. 1, a prediction apparatus 100 collects time-series growth environment information such as the temperature, humidity, CO₂ concentration, and solar radiation of a crop cultivation site and information on pests and diseases of crops according to changes in a growth environment from a public database, constructs a data set, and performs machine learning on the data set to create a model for predicting the risk of pests and diseases of crops according to changes in the growth environment.

The risk prediction model is used to predict the risk of pests and diseases of crops. For example, the prediction apparatus 100 receives accumulated growth environment information on a target cultivation site, predicts that pests and diseases will occur due to an incorrect growth environment in the target cultivation site through the risk prediction model, and causes a rapid action to be taken before pests and diseases occur in crops.

Conventionally, the occurrence of pests and diseases is predicted by creating a prediction model using factors such as crop genomes, crop nutrients, and microbial pathogens, but it is difficult to collect and manage factors such as crop genomes, crop nutrients, and microbial pathogens, and thus there are limitations in using the factors. However, the prediction apparatus 100 of the present embodiment can predict the occurrence of pests and diseases in crops only with crop growth environment information in general situations by using public environmental data that can be relatively easily collected and applying a deep learning method.

In addition, since the prediction apparatus 100 predicts the occurrence of pests and diseases of crops using only growth environment information, it can be universally applied to various facilities and crops.

In the present embodiment, a crop cultivation site may employ facility horticulture or open field horticulture. However, in the present embodiment, facility horticulture may be preferable because the environment of a cultivation site needs to be artificially controlled according to an environment creation recipe.

In the present embodiment, growth environment information may basically include temperature and humidity information of a cultivation site, and may further include at least one of the rainfall amount, light amount, CO₂ concentration, light wavelength, or soil PH depending on the characteristics of the cultivation site, the type of crop, and the like.

As an example, the growing environment information may vary depending on the type of horticulture.

For example, the growth environment information may include facility horticultural environment information including at least one of temperature, humidity, light amount, CO₂ concentration, dew point, or soil temperature, and open field horticulture including at least one of temperature, humidity, rainfall amount, soil temperature, soil humidity, wind speed, wind direction or dew point.

In the present embodiment, time-series growth environment information may refer to information accumulated over time about past growth environment changes (for example, changes in temperature and humidity) on a daily or weekly basis in a cultivation site.

In the present embodiment, pests and diseases refer to strawberry gray mold, powdery mildew, mites, scales, aphids, greenhouse whiteflies, shield bugs, and root flies, and include any pest and disease that may occur in crops in addition to those listed.

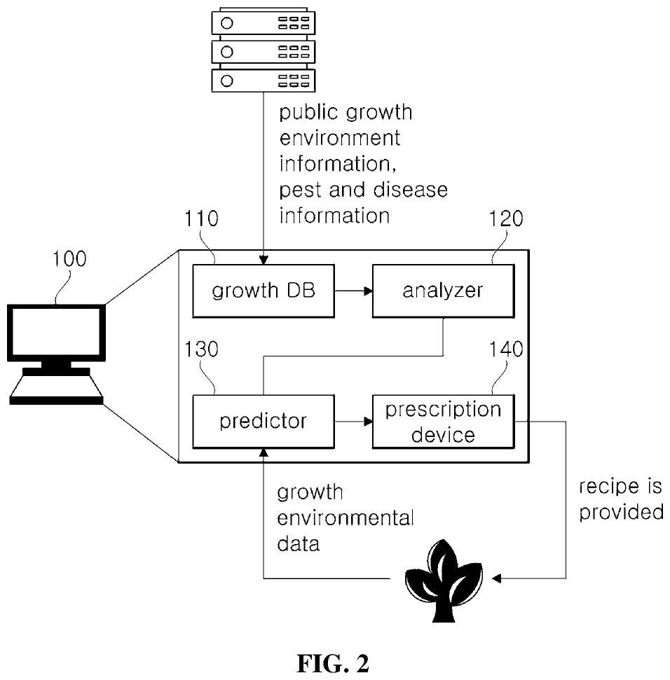

FIG. 2 is a block diagram showing the detailed configuration of the prediction apparatus 100 illustrated in FIG. 1.

As shown in FIG. 1 and FIG. 2, the prediction apparatus 100 includes a growth DB 110, an analyzer 120, a predictor 130, and a prescription device 140.

The growth DB 110 constructs a data set including time-series growth environment information of crop cultivation sites and information on pests and diseases in the crop cultivation sites according to the growth environment.

The growth DB 110 receives time-series growth environment information and information on pests and diseases in the crop cultivation site according to the growth environment from a public database called “plant disease-causing data set” provided by AI-hub (aihub.or.kr) and constructs a data set for machine learning.

The data set constructed in the growth DB 110 is data regarding changes in growth environments (temperature, humidity changes, and the like) of crops grown at various cultivation sites (or cultivation facilities) and diseases caused by environmental changes.

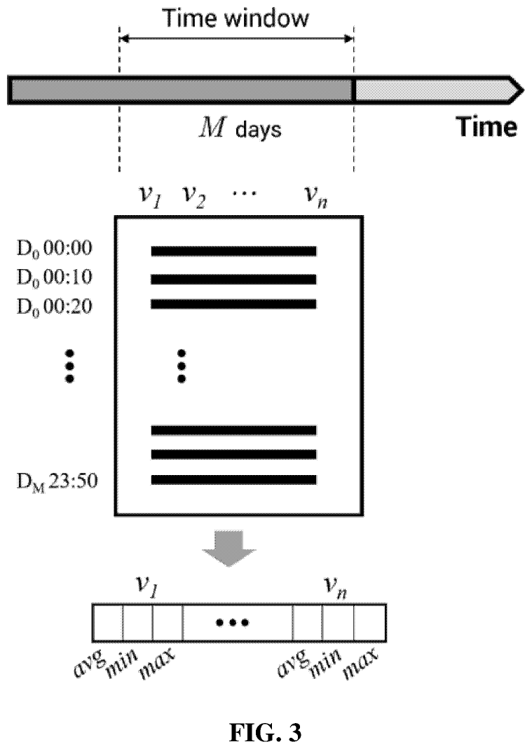

For example, an example of the data set constructed in the growth DB 110 will be described. The growth DB 110 cumulatively collects disease occurrence data and time-series environment information from at least 48 hours before the occurrence of pests and diseases (refer to FIG. 3). For reference, FIG. 3 is a simplified representation of a data format obtained during a data measurement period and transformation to a one-dimensional vector, in which M is set to 2 because records of 48 hours have been obtained.

In the present embodiment, a data set is constructed by collecting growth environment information and information on pests and diseases with respect to five crops (strawberry, pepper, grape, tomato, and paprika). However, the types and numbers of crops included in the data set are not limited.

Grape data includes dew point data from temperature and humidity records, strawberry, pepper, and tomato data includes dew points and CO₂ concentrations, and paprika data includes solar radiation measurement values. Such differences in the types of collected data may inevitably occur due to the diversity of environment information collection facilities in the actual cultivation sites or crop types.

In addition, the growth DB 110 collected data on strawberry gray mold measured from November 2020 to May 2021 as data to validate the model trained using AI-hub. During this period, growth environment information such as the air temperature of a strawberry facility, solar radiation, relative humidity, and dew point was collected every 10 minutes, and the proportion of infected strawberries in the beds was measured. Unlike pest and disease data sets including binary crop condition information, the data is obtained as continuous values because the proportion of pest-infested crops among all crops is measured.

The analyzer 120 create a risk model for pests and diseases of crops according to changes in the growth environment using the data set constructed in the growth DB 110.

The analyzer 120 may apply a deep learning-based method to construct the risk model for predicting whether pests and diseases will occur at a specific point in time based on past growth environments.

As an example, the analyzer 120 may be used as an autoencoder-based regression model.

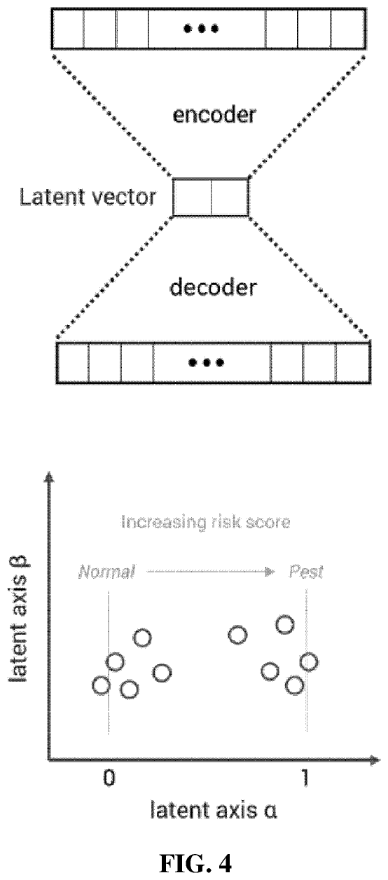

The specific operation of the analyzer 120 to predict a risk based on an autoencoder will be described again with reference to FIG. 4 to FIG. 8 below, and the predictor 130 and the prescription device 140 will be described first.

The predictor 130 receives cumulative input of growth environment information of a target cultivation site and calculates the risk of pests and diseases that may occur in crops in the target cultivation site using the risk prediction model.

The target cultivation site may mean a target in which crops are growing and for which pests and diseases are predicted using the above-described risk prediction model.

The cumulative input of growth environment information may mean information accumulated over time about past growth environment changes (for example, changes in temperature, humidity, and the like) on a daily or weekly basis.

The predictor 130 may calculate risk level 1, which indicates that strawberry gray mold may occur if two days have passed in a state in which the temperature is lower or higher than a reference value in the growth environment of the target cultivation site, and calculate risk level 2, which indicates that the probability of strawberry gray mold occurring becomes higher if four days have passed.

The prescription device 140 creates an environment creation recipe by which the occurrence of pests and diseases can be prevented by creating an environment in the target cultivation site on the basis of the risk calculated by the predictor 130.

The environment creation recipe may be at least one of temperature control, humidity control, light amount control, light wavelength control, ventilation cycle control, or water spraying for the cultivation site.

For example, in the case of facility horticulture, the environment creation recipe may be at least one of temperature control, humidity control, light amount control, CO₂ control, dew point control, or soil temperature control.

The prescription device 140 may receive information on environment creation facilities (e.g., heaters, humidifiers, light amount controllers, wavelength converters, and the like) previously provided in the cultivation site, and create a recipe by which the growth environment can be changed through the facilities provided in the cultivation site.

Meanwhile, the analyzer 120 can continuously calculate the risk of pests and diseases for the target cultivation site even if the environment creation recipe is created by the prescription device 140 and provided to the target cultivation site. In addition, if the risk of pests and diseases increases although the environment creation recipe has been provided to the target cultivation site, the prescription device 140 may regenerate an environment creation recipe at a higher level (e.g., higher intensity).

Hereinafter, the operation of predicting pests and diseases through machine learning on a data set will be described.

FIG. 4 is a diagram illustrating an autoencoder structure and optimal embedding for a latent space.

For reference, the analyzer 120 may use an autoencoder-based regression model.

As shown in FIG. 4, the autoencoder-based model predicts crop conditions using environmental data measured over the past two days from a prediction point.

The analyzer 120 takes an input vector representing observed values of the two days. Then, cumulative environmental data of the two days is converted into a one-dimensional vector and used as input to the model. For all environmental variables included in the data, the average, minimum, and maximum values of measured values during the period are calculated, and all these values are concatenated to form a one-dimensional vector representing the observation period. As a result, an input vector of length 3n is generated for a facility measuring n environmental variables (refer to FIG. 3).

The risk prediction model is composed of an encoder composed of two layers with the same length as the input vector, a decoder having the same structure as the encoder, and a two-dimensional latent vector. While a typical autoencoder learns by using an error between an input vector and a reconstruction vector as a loss, a degree to which a label indicating a condition of a crop is predicted is added to a loss function in the present embodiment.

In a training stage, the mean square error between the input vector and the reconstruction vector and the distance between reference points on the alpha axis corresponding to the label are added and used as a loss function to group normal data points and pest data points, respectively.

For normal data, reference point alpha=0, and for pest data, alpha=1. Since the data points are aligned along the alpha axis, continuous values of the alpha coordinate of data points that can be regarded as a risk score is obtained. Therefore, although the model has been trained using binary labeled data, the prediction model can be used as an autoencoder-based regression model.

In addition, the risk prediction model is trained using the data set to classify environmental vectors based on labels such as the presence or absence of crop diseases or pests. In all cases, 80% of the data is used as training data and the rest is used as test data. During the learning process, the learning rate, weight reduction, and epoch are optimized for crops and pests, while the batch size is fixed to 64. After hyperparameter optimization, 5-fold cross-validation is performed. The risk score for each trial is used for further analysis.

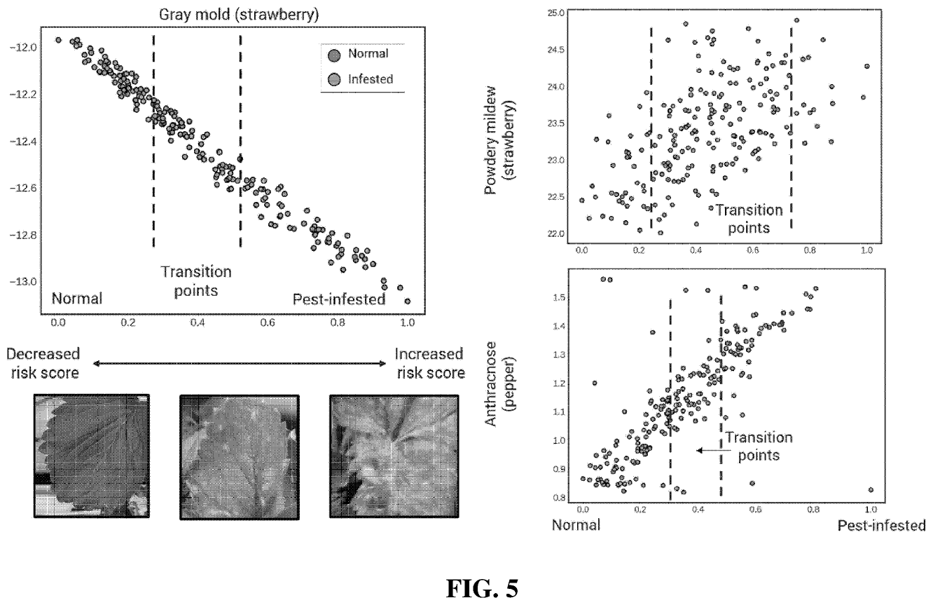

FIG. 5 is a diagram showing two-dimensional embedding of test data.

In the present embodiment, test data sets are used for most crops and pests to classify normal crops and infested crops according to the state of a latent space.

Data points tend to be classified and sorted from a normal cluster to an infested cluster on coordinates α=0 to α=1.

The prediction model is trained to collect normal points near α=0 and pest-infested points near α=1 in the latent space due to the loss function used in the prediction model.

The similarity of accumulated environmental features is also represented as the distance between points. In particular, a section where normal and infested samples are mixed indicates a transition stage. This means that many samples are changing from a normal state to an infested state.

In the transition stage, the number of damaged crops gradually increases as the growth environment changes. This shows that the prediction model can be used as a model for predicting the onset of a disease by increasing a risk score before the onset of the disease since it provides continuous risk scores rather than a binary classification result.

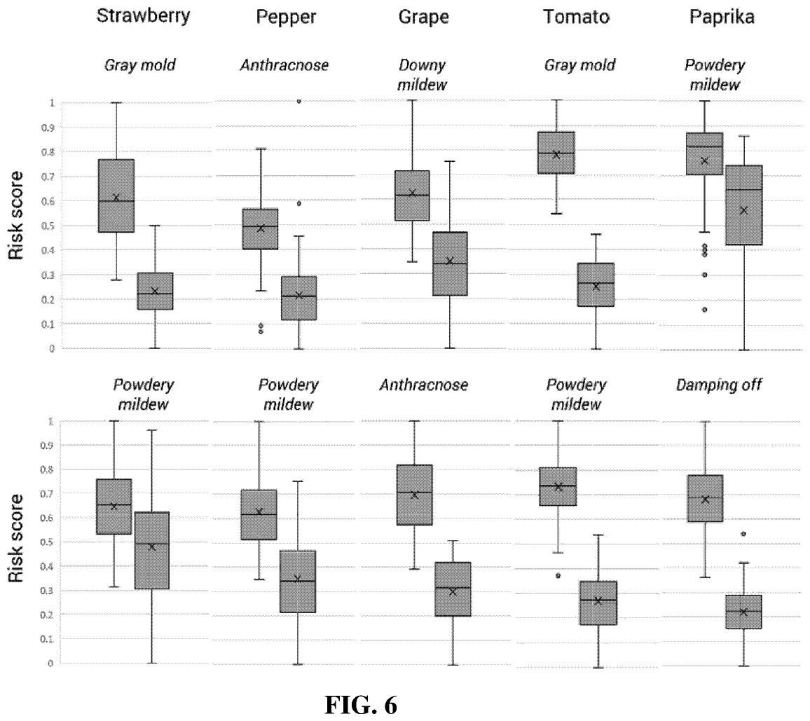

FIG. 6 is a diagram showing a distribution of risk scores for normal and infested samples for each crop and each pest and disease.

As shown in FIG. 6, how well the condition of crops can be predicted was tested from accumulated environmental data using risk scores from the latent space. In all cases, the risk score was significantly higher in infested samples than in normal cases (p<0.05), and some overlapping results were also found in the transition stage.

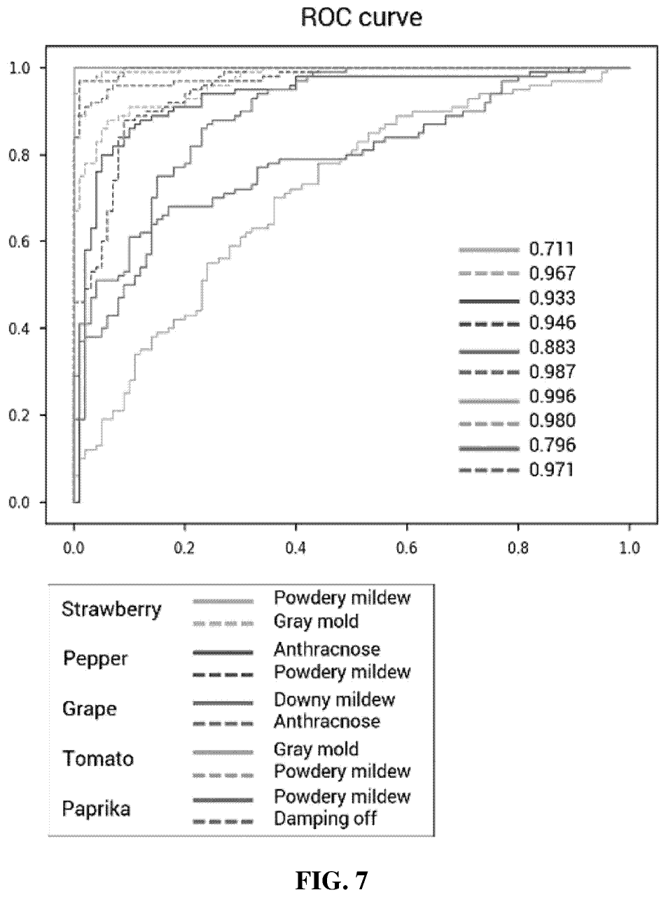

FIG. 7 is a diagram showing prediction results for crops and pests and diseases.

As shown in FIG. 7, the analyzer 120 evaluates the crop pest and disease prediction model using the ROC curve. Normal and infested samples are very well differentiated in the case of gray mold on strawberries, tomatoes, and paprika, but in some cases, such as powdery mildew, extensive overlapping can be seen.

The risk score was used as a ranking for classifying crop conditions and drawing ROC curves. The average of AURC was 0.917, showing that the model can classify pests and diseases with high performance.

In particular, classification performance is consistent with overlap in risk scores. In the case of powdery mildew, the classification performance appears to be low because many risk scores of normal and infested samples overlap.

The overlap between low prediction performance and high risk scores can be interpreted as the presence of influential factors other than the obtained environmental variables that affect the occurrence of pests and diseases.

In the present embodiment, environmental variables such as solar radiation and relationships between hosts and molds may be additionally considered in order to improve the performance of the risk prediction model.

Therefore, the relationship between disease severity and risk scores was further investigated.

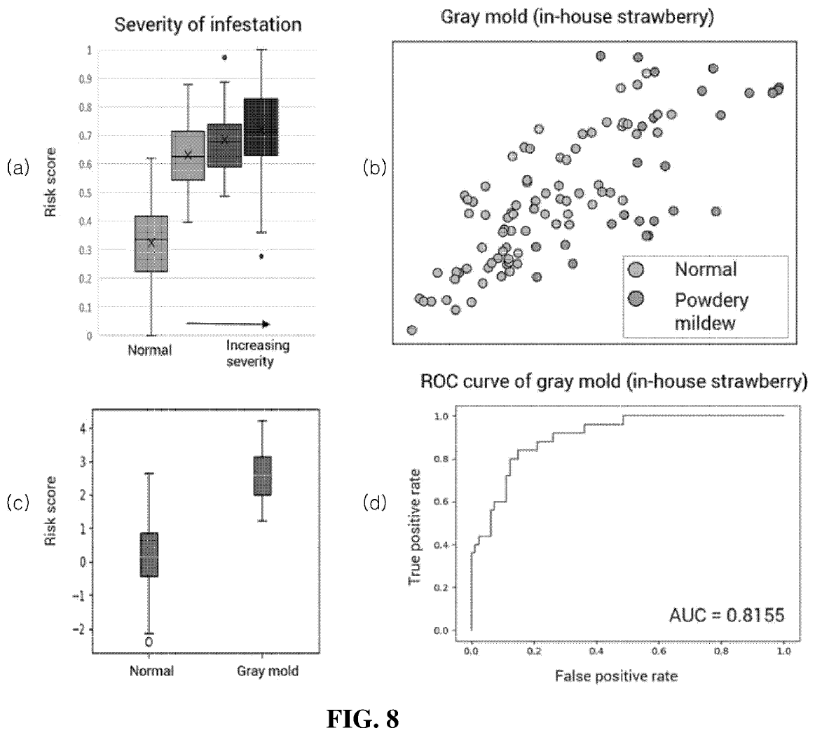

FIG. 8(a) is a diagram showing a risk score distribution corresponding to the severity of an observed occurrence.

As shown in FIG. 8(a), a predicted risk score for each observed value was indicated using paprika damping-off data from AI-hub, which includes a disease severity index. The risk prediction model is trained with binary labels, but the risk score tends to increase as disease severity increases.

FIG. 8(a) shows that the prediction model can find the relationship between a crop exposure environment and the occurrence and development of pests and diseases. However, since the difference in risk scores between occurrence stages is less than the difference between normal and infested samples, it is important to control the environment of the facility before the transition point to maintain crops in a normal state.

Unlike binary classification, the prediction model uses the risk score as a surrogate measure for occurrence prediction, and can be helpful as a technical model in tactical decision-making for pest prevention and management.

To test the possibility of a decision-making assistant for crop growth environment management, changes in the latent space are observed while adjusting environmental data for one piece of strawberry gray mold and powdery mildew test data in a crop pest occurrence data set.

The model can be used to prevent pests and diseases by managing the environment in a way of maintaining a normal state by lowering the risk score due to movement of data points in the latent space driven by changes in the growth environment.

FIG. 8(b) is a diagram showing verification of a gray mold prediction model using a data set.

In order to show that the model trained with the crop pest occurrence data set can be applied to other data sets, the risk prediction model of the present embodiment was tested with a data set including strawberry gray mold data. The test data was embedded in the latent space, and normal and infested samples were found to be well aligned.

The distributions of risk scores for normal and infested samples also matched test results of the crop pest and disease occurrence data set. In addition, prediction performance was evaluated by AUROC, and AUROC was 0.8755, showing satisfactory performance (refer to FIG. 8(c) and FIG. 8(d)).

However, the range of predicted risk scores was different. This may be caused by differences in species and environmental varieties of strawberries or molds due to a facility condition such as soil quality. This means that a certain degree of overfitting occurs because the input data cannot include all influencing variables on pests. Although sorting according to the risk of pest occurrence is possible even with a pre-trained model, the scale of risk scores rarely matches.

### Embodiment 2

Embodiment 2 relates to technology for determining the types and progress of pests and diseases with high accuracy by analyzing captured images of crops and presenting a recipe by which the pests and diseases can be intensively cured in a case where the pests and diseases have occurred although the growth environment of the cultivation site has been changed in advance since there is a risk of occurrence of pests and diseases in the target cultivation site in Embodiment 1.

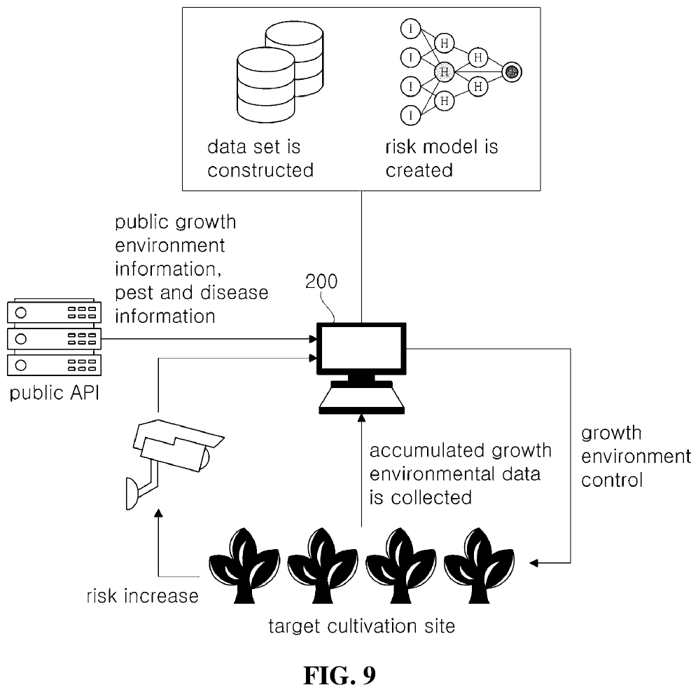

FIG. 9 is a schematic diagram showing an overall system for predicting the risk of pests and diseases of crops using time-series environmental data according to Embodiment 2 of the present invention.

As shown in FIG. 9, a prediction apparatus 200 of Embodiment 2 receives captured images of crops when pests and diseases have been found in the crops after creation of a new growth environment in a target cultivation site according to a predicted risk of pests and diseases.

The prediction apparatus 200 analyzes the images of the crops to determine the correct types and progress of the pests and diseases and provides a control recipe for controlling the determined pests and diseases.

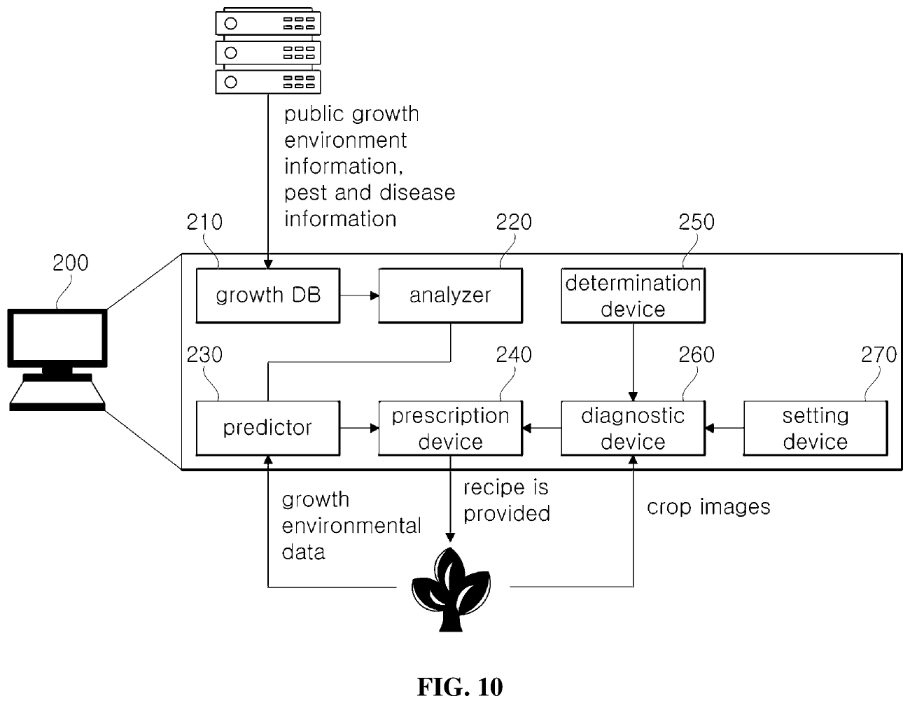

FIG. 10 is a block diagram showing the detailed configuration of the prediction apparatus 200 illustrated in FIG. 9.

As shown in FIG. 10, the prediction apparatus 200 includes a growth DB 210, an analyzer 220, a predictor 230, a prescription device 240, a determination device 250, a diagnostic device 260, and a setting device 270.

The growth DB 210, the analyzer 220, the predictor 230, and the prescription device 240 of Embodiment 2 are the same as the growth DB 110, the analyzer 120, the predictor 130, and the prescription device 140 of Embodiment 1, and thus redundant description will be omitted, and the determination device 250, the diagnostic device 260, and the setting device 270 newly added to Embodiment 1 will be described. In addition, although the growth DB 210 and the prescription device 240 are the same as those in Embodiment 1, newly added functions thereof will also be described.

The growth DB 210 further constructs a data set including images of normal crops and images of pest-infested crops. For example, the growth DB 210 may construct a data set by receiving images of normal crops and images of pest-infested crops from a public database. The method of constructing the data set is not limited to any one method.

The determination device 250 determines pests and diseases by ensemble learning a pest detection algorithm through the crop image data set, and selects the optimal pest detection algorithm according to the type of crop and the growth environment information.

For example, the determiner 250 reads pests by ensemble learning pest detection algorithms through crop image data sets, and selects an optimal pest detection algorithm according to the types of crops and information on the growth environment.

For example, the reason why the determination device 250 selects the optimal pest detection algorithm by ensemble learning pest detection algorithms is that the types of pests and diseases that occur will vary depending on the types of crops, and thus the optimal pest detection algorithm by which pests and diseases that may occur depending on the types of crops and the growth environment information can be determined most accurately can be selected.

For example, if pests and diseases occur in strawberries and the strawberry growth environment has been maintained for a certain period of time at a temperature higher than a reference temperature, a pest detection algorithm that is advantageous for detecting strawberry powdery mildew with a high probability of occurrence can be selected.

As another example, if pests and diseases occur in strawberries and the strawberry growth environment has been maintained for a certain period of time at a humidity higher than a reference humidity, a pest detection algorithm that is advantageous for detecting strawberry gray mold with a high probability of occurrence can be selected.

The pest detection algorithm used in the determination device 250 may be an image analysis algorithm. For example, a convolutional neural network (CNN) and YOLO (You Only Look Once) may be used as specific examples of the image analysis algorithm.

The CNN is a network for extracting features from input image data through convolution operations and detecting objects included in the image data through the extracted features and includes feature extraction layers for extracting feature information of objects and fully connected layers for classifying objects using extracted feature information. In other words, the CNN can be defined as an object detection technique for localizing geometric information such as the size or position of a specific object included in image data and classifying the specific object.

YOLO divides each image into S×S grids and calculates the reliability of the grids. The reliability reflects accuracy when recognizing an object in a grid. Initially, a bounding box that is far from object recognition is set, but a bounding box with the highest object recognition accuracy can be obtained by calculating the reliability and adjusting the position of the bounding box. To calculate whether objects are included in the grids, an object class score is calculated. As a result, a total of S×S×N objects is predicted. Most of the grids have low reliability, and to increase the reliability, surrounding grids are merged and then a threshold is set to remove unnecessary parts.

The determination device 250 may use any one of voting, bagging, boosting, and stacking methods in ensemble learning of pest detection algorithms.

Voting is a method of predicting a final result by voting on results obtained by using various types of algorithms.

Bagging is a method of performing voting by training the same algorithm with different data samples.

Boosting is a method in which learning and prediction are performed in such a manner that multiple algorithms perform learning sequentially and a weight is assigned to the next algorithm such that correct prediction can be performed on data for which prediction of the previous algorithm is incorrect.

Stacking is a method of predicting results by making prediction result values of several different models into training data and retraining the models as other models (meta models).

Meanwhile, although the determination device may select an optimal algorithm for determining pests and diseases by ensemble learning pest detection algorithms, it may also select a predetermined pest detection algorithm. For example, the determination device can select an optimal algorithm for determining pests and diseases by ensemble learning pest detection algorithms only when it is difficult to determine pests and diseases using a predetermined pest detection algorithm.

The diagnostic device 260 analyzes images of crops provided from an imaging device installed in the target cultivation site to determine the types and progress of pests and diseases occurring in the crops.

Here, the imaging device may refer to a camera pre-installed in the cultivation site, but may also refer to a mobile phone or a portable imaging device of a user.

Specifically, the diagnostic device 260 cumulatively collects growth environment information of the target cultivation site and determines pests and diseases with a high probability of occurrence in the collected growth environments (e.g., high temperature) using an optimal pest detection algorithm with the highest accuracy. For reference, the optimal pest detection algorithm may be the algorithm selected in the determination device 250.

Therefore, the diagnostic device 260 of the present embodiment can improve the accuracy of determination of pests and diseases by applying the optimal pest detection algorithm and minimize the waste of resources and time required for algorithm calculation due to determination failure when an inappropriate algorithm is used.

Meanwhile, the diagnostic device 260 may periodically collect captured images of crops in the target cultivation site, but may minimize the waste of resources required for algorithm calculation by not performing a pest detection method for analyzing crop images before pests and diseases occur.

In addition, even before pests and diseases occur, the diagnostic device 260 may collect captured images of crops at the target cultivation site and perform pest and disease detection to minimize the waste of resources required for unnecessary algorithm calculations due to constant operation of the algorithm if the risk prediction level of the predictor 230 is equal to or higher than the reference level.

For reference, the preset reference level for risk may be changed organically through continuous upgrades of the constructed data set, or may be set by the administrator.

### Embodiment 3

Embodiment 3 relates to a method for predicting the risk of pests and diseases of crops using the prediction apparatuses of Examples 1 and 2.

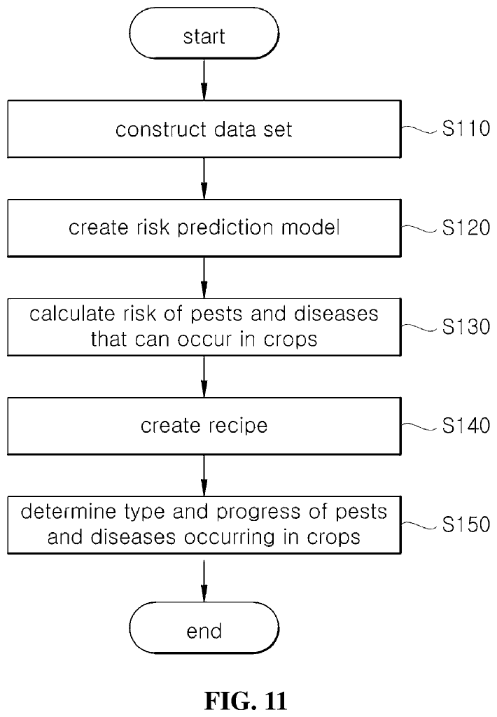

FIG. 11 is a flowchart showing a method for predicting the risk of pests and diseases of crops according to Embodiment 3 of the present invention.

As shown in FIG. 11, the method of Embodiment 3 includes the steps of constructing a data set (S110), creating a risk prediction model (S120), calculating the risk of pests and diseases that may occur in crops (S130), creating a recipe (S140), and determining the type and progress of pests and diseases (S150).

In the step of constructing a data set (S110), the growth DB constructs a data set including time-series growth environment information of a crop cultivation site and pest and disease information of the crop cultivation site according to the growth environment.

The growth DB constructs a data set for machine learning by receiving time-series growth environment information and pest and disease information of the crop cultivation site according to the growth environment from a public database called “plant disease-causing data set” provided by AI-hub.

In the step of creating a risk prediction model (S120), the analyzer creates a risk model for pests and diseases of crops according to changes in the growth environment using the data set constructed in the growth DB.

The analyzer may apply a deep learning-based method to construct a risk model for predicting whether pests and diseases will occur at a specific point in time based on past growth environments.

As an example, the analyzer may be used as an autoencoder-based regression model.

In the step of calculating the risk of pests and diseases that may occur in crops (S130), the predictor receives cumulative input of growth environment information of the target cultivation site and calculates the risk of pests and diseases that may occur in crops in the target cultivation site using the risk prediction model.

The target cultivation site may mean a target in which the crops are growing and for which pests and diseases are predicted using the above-described risk prediction model.

The cumulative input of growth environment information may mean information accumulated over time about past growth environment changes (for example, changes in temperature and humidity) on a daily or weekly basis.

The predictor may calculate risk level 1, which indicates that strawberry gray mold may occur if two days have passed in a state in which the temperature is lower or higher than a reference value in the growth environment of the target cultivation site, and calculate risk level 2, which indicates that the probability of strawberry gray mold occurring becomes higher if four days have passed.

In the step of creating a recipe (S140), the prescription device creates an environment creation recipe by which the occurrence of pests and diseases can be prevented by creating an environment in the target cultivation site on the basis of the risk calculated by the predictor. The environment creation recipe may be at least one of temperature control, humidity control, light amount control, light wavelength control, ventilation cycle control, or water spraying for the cultivation site.

For example, the prescription device may receive information on environment creation facilities (e.g., heaters, humidifiers, light amount controllers, and wavelength converters) previously provided at the cultivation site, and create a recipe by which the growth environment can be changed through the facilities provided at the cultivation site.

In the step of determining the types and progress of pests and diseases (S150), pests and diseases are determined by analyzing captured images of crops when pests and diseases occur although the growth environment of the cultivation site are changed in advance due to the risk of pests and diseases at the target cultivation site.

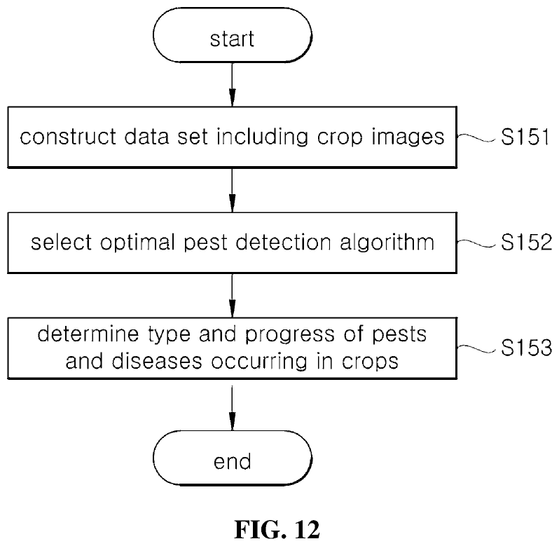

FIG. 12 is a flowchart showing a method for determining the types and progress of pests and diseases by analyzing images of crops in Embodiment 3.

The step of determining the types and progress of pests and diseases (S150) includes a step of constructing a data set including images of crops (S151), a step of selecting an optimal pest detection algorithm (S152), and a step of determining the types and progress of pests and diseases (S153).

In the step of constructing a data set including images of crops (S151), the growth DB further constructs a data set including images of normal crops and images of pest-infested crops. For example, the growth DB can construct a data set by receiving images of normal crops and images of pest-infested crops from a public database. The method of constructing the data set is not limited to any one method.

In the step of selecting an optimal pest detection algorithm, the determination device determines pests and diseases by ensemble learning pest detection algorithms through the crop image data set, and selects an optimal pest detection algorithm according to the type of crops and the growth environment information.

In the step of determining the types and progress of pests and diseases (S153), the diagnostic device analyzes the images of crops provided from an imaging device installed in the target cultivation site and determines the types and progress of pests and diseases occurring in the crops.

Specifically, the diagnostic device cumulatively collects growth environment information of the target cultivation site and determines pests and diseases with a high probability of occurrence in the collected growth environment (e.g., high temperature) using the optimal pest detection algorithm with the highest accuracy. For reference, the optimal pest detection algorithm may be the algorithm selected by the determination device.

Meanwhile, the diagnostic device may minimize the waste of resources required for unnecessary algorithm calculations by collecting captured images of crops in the target cultivation site and performing pest and disease detection only when the risk prediction level of the predictor is equal to or higher than the reference level.

Although the present invention has been described above with reference to several embodiments, those skilled in the art will understand that the present invention can be modified and changed in various manners without departing from the spirit and scope of the present invention as set forth in the claims below.

Additionally, the invention regarding the method among the embodiments described above may be implemented as a program or as a computer-readable recording medium storing the program.

In other words, the present invention can be implemented in the form of an application, implemented as a software program executed in mobile terminals such as smartphones and tablet computers operating on Android of Google or iOS of Apple, implemented as a software program executed in wearable devices such as Google Glass, Apple Watch, Samsung Galaxy Watch, and smartwatch, or implemented as a software program executed in laptop computers or desktop computers operating on Microsoft Windows or Chrome OS of Google.

In addition, the partial functions of the above-described device or system may be provided by being included in a computer-readable recording medium by tangibly implementing a program including instructions for implementing the same. A computer-readable recording medium may include program instructions, data files, data structures, etc. alone or in combination. Examples of the computer-readable recording medium include magnetic media such as hard disks, floppy disks and magnetic tapes, optical media such as CD-ROMs and DVDs, magneto-optical media such as floptical disks, and hardware devices specially configured to store and carry out program instructions, such as ROMs, RAMs, flash memories, and USB memories.

According to an embodiment of the present invention, it is possible to minimize the use of chemicals by predicting the risk of pests and diseases that may occur in crops using large-scale environmental data on multiple crops and pests and diseases and taking action in advance.

According to an embodiment of the present invention, it is possible to predict the occurrence of pests and diseases in crops only with crop growth environment information in general by using public environmental data that can be relatively easily collected and applying a deep learning method.

According to an embodiment of the present invention, it is possible to minimize the waste of resources necessary for unnecessary algorithm calculations by collecting crop images of a target cultivation site and performing pest detection only when a risk prediction level of a predictor is equal to or higher than a reference level.

The present invention was derived as a result of the following research and development project ordered by the Rural Development Administration.

Project identification number: 1395066915

Project number: PJ01533203

Department name: Rural Development Administration

Name of project management (professional) organization: Rural Development Administration

Research project title: Agricultural technology management research—Agricultural big data collection and productivity improvement model development

Project title: Development of image utilization program for early detection of major strawberry pests

Contribution rate: 1/1

Name of project carrying out organization: Sherpa Space Co., Ltd.

Research period: May 1, 2020 to Dec. 31, 2024

What is claimed is:

1. An apparatus for predicting a crop pest and disease risk using time-series environmental data, the apparatus comprising:
a growth DB for constructing a data set including time-series growth environment information including temperature and humidity of a crop cultivation site and information on pests and diseases of crops according to changes in a growth environment;
an analyzer configured to perform machine learning on the data set to create a risk prediction model for pests and diseases of crops according to changes in the growth environment;
a predictor configured to receive accumulated growth environment information of a target cultivation site and to calculate a risk of pests and diseases occurring in crops at the target cultivation site using the risk prediction model; and
a prescription device configured to generate an environment creation recipe for the target cultivation site on the basis of the calculated risk.

2. The apparatus of claim 1, wherein the growth environment information includes facility horticulture environment information including at least one of a temperature, a humidity, a light amount, a CO₂ concentration, a dew point, or a soil temperature, and open field horticulture environment information including at least one of a temperature, a humidity, a rainfall amount, a soil temperature, a soil humidity, a wind speed, a wind direction, or a dew point.

3. The apparatus of claim 1, wherein the environment creation recipe includes at least one of temperature control, humidity control, light amount control, CO₂ control, dew point control, or soil temperature control in the case of facility horticulture.

4. The apparatus of claim 1, further comprising a diagnostic device configured to analyze images of crops provided from an imaging device installed at the target cultivation site to determine the type and progress of pests and diseases occurring in the crops.

5. The apparatus of claim 4, wherein the growth DB further constructs a data set including images of normal crops and images of pest-infested crops,
the apparatus further comprising a determination device configured to determine pests and diseases through ensemble learning of pest detection algorithms using the crop image data set and to select an optimal pest detection algorithm according to the type of crops and the growth environment information,
wherein the diagnostic device determines the type and progress of pests and diseases occurring in the crops using the selected pest detection algorithm.

6. The apparatus of claim 4, wherein the prescription device further generates a control recipe depending on the determined type and progress of pests and diseases.

7. The apparatus of claim 4, wherein the diagnostic device receives the images of the crops from the imaging device only when the risk calculated by the predictor is equal to or higher than a preset reference level.

8. The apparatus of claim 4, further comprising a setting device configured to instruct the imaging device to change an imaging cycle depending on the type and progress of pests and diseases when the type and progress of pests and diseases are determined by the diagnostic device.

9. A method for predicting a crop pest and disease risk using time-series environmental data by a risk prediction apparatus, the method comprising:
constructing, by a growth DB of the prediction apparatus, a data set including time-series growth environment information including temperature and humidity of a crop cultivation site and information on pests and diseases of crops according to changes in a growth environment;
performing, by an analyzer of the prediction apparatus, machine learning on the data set to create a risk prediction model for pests and diseases of crops according to changes in the growth environment;
receiving accumulated growth environment information of a target cultivation site and calculating a risk of pests and diseases occurring in crops at the target cultivation site using the risk prediction model by a predictor of the prediction apparatus; and
generating, by a prescription device of the prediction apparatus, an environment creation recipe for the target cultivation site on the basis of the calculated risk.

10. The method of claim 9, wherein the growth environment information includes facility horticulture environment information including at least one of a temperature, a humidity, a light amount, a CO₂ concentration, a dew point, or a soil temperature, and open field horticulture environment information including at least one of a temperature, a humidity, a rainfall amount, a soil temperature, a soil humidity, a wind speed, a wind direction, or a dew point.

11. The method of claim 9, wherein the environment creation recipe includes at least

12. The method of claim 9, further comprising analyzing, by a diagnostic device of the prediction apparatus, images of crops provided from an imaging device installed at the target cultivation site to determine the type and progress of pests and diseases occurring in the crops.

13. The method of claim 9, wherein the determining of the type and progress of pests and diseases occurring in the crops comprises:
further constructing, by the growth DB, a data set including images of normal crops and images of pest-infested crops;
determining pests and diseases through ensemble learning of pest detection algorithms using the crop image data set and selecting an optimal pest detection algorithm according to the type of crops and the growth environment information by a determination device of the prediction apparatus; and
determining, by the diagnostic device, the type and progress of pests and diseases occurring in the crops using the selected pest detection algorithm.

14. The method of claim 12, wherein the prescription device further generates a control recipe depending on the determined type and progress of pests and diseases.

15. The method of claim 12, wherein the diagnostic device receives the images of the crops from the imaging device only when the risk calculated by the predictor is equal to or higher than a preset reference level.
